(19) United States
(12) Patent Application Publication
(10) Pub. No.: US 2026/0343889 A1
(43) Pub. Date: Oct. 29, 2026

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Sang Min KANG, Suwon-si (KR); Ji Hoon LEE, Suwon-si (KR)

(73) Assignee: SAMSUNG ELECTRONICS CO., LTD., Suwon-si (KR)

(21) Appl. No.: 19/463,919

(22) Filed: Jan. 29, 2026

(30) Foreign Application Priority Data
Apr. 25, 2025 (KR) 10-2025-0054199

(51) Int. Cl. H10B 43/35; H10B 43/27

(52) U.S. Cl. CPC H10B 43/35; H10B 43/27

(57) ABSTRACT

A semiconductor memory device may include: a substrate; a stack structure on the substrate, the stack structure including gate electrodes and a mold insulating films that are alternately stacked on top of each other in a first direction intersecting an upper surface of the substrate; a channel structure extending in the first direction through the stack structure, the channel structure including a semiconductor film and a data storage film between the semiconductor film and the gate electrodes; and a high dielectric-constant film including: a first high dielectric-constant metal oxide film in contact with the data storage film; and a second high dielectric-constant metal oxide film between the first high dielectric-constant metal oxide film and at least one of the gate electrodes, wherein the data storage film includes a tunnel insulating film, a charge storage film, and a blocking insulating film on the semiconductor film.

### CROSS-REFERENCE TO RELATED APPLICATION

This application claims priority from Korean Patent Application No. 10-2025-0054199, filed on Apr. 25, 2025, in the Korean Intellectual Property Office, the disclosure of which is herein incorporated by reference in its entirety.

### BACKGROUND

### 1. FIELD

Some embodiments of the present disclosure relate to a semiconductor memory device and an electronic system including the same.

### 2. Description of Related Art

As a semiconductor memory device capable of storing high-capacity data therein is required in an electronic system, schemes of increasing data storage capacity of the semiconductor memory device are being studied. In one of the schemes of increasing the data storage capacity of the semiconductor memory device, a semiconductor memory device including memory cells arranged three-dimensionally instead of memory cells arranged two-dimensionally has been proposed.

### SUMMARY

According to some embodiments of the present disclosure, a semiconductor memory device with improved yield and reliability may be provided.

According to some embodiments of the present disclosure, an electronic system including a semiconductor memory device with improved yield and reliability may be provided.

According to some embodiments of the present disclosure, a method for manufacturing a semiconductor memory device with improved yield and reliability may be provided.

According to some embodiments of the present disclosure, a semiconductor memory device may include: a substrate; a stack structure on the substrate, the stack structure including gate electrodes and a mold insulating films, wherein the gate electrodes and the mold insulating films are alternately stacked on top of each other in a first direction intersecting an upper surface of the substrate; a channel structure extending in the first direction through the stack structure, the channel structure including a semiconductor film and a data storage film between the semiconductor film and the gate electrodes; and a high dielectric-constant film including: a first high dielectric-constant metal oxide film in contact with the data storage film; and a second high dielectric-constant metal oxide film between the first high dielectric-constant metal oxide film and at least one of the gate electrodes, wherein the data storage film includes a tunnel insulating film, a charge storage film, and a blocking insulating film sequentially disposed on the semiconductor film, wherein the blocking insulating film is between the high dielectric-constant film and the charge storage film, and wherein the first high dielectric-constant metal oxide film includes a first metal oxide doped with an impurity element.

According to some embodiments of the present disclosure, a semiconductor memory device may include: a substrate; a stack structure on the substrate, the stack structure including gate electrodes and mold insulating films, wherein the gate electrodes and the mold insulating films are alternately stacked on top of each other in a first direction intersecting an upper surface of the substrate; a channel structure extending in the first direction through the stack structure, the channel structure including a semiconductor film and a data storage film between the semiconductor film and the gate electrodes; and a high dielectric-constant film between the channel structure and at least one of the gate electrodes and between at least one of the gate electrodes and at least one of the mold insulating films adjacent to the at least one of the gate electrodes, wherein the high dielectric-constant film includes: a first high dielectric-constant metal oxide film in contact with the channel structure and the at least one of the mold insulating films, wherein the first high dielectric-constant metal oxide film includes a first metal oxide doped with an impurity element; and a second high dielectric-constant metal oxide film between the first high dielectric-constant metal oxide film and the at least one of the gate electrodes.

According to some embodiments of the present disclosure, an electronic system may include: a circuit board; a semiconductor memory device on the circuit board; and a controller on the circuit board and electrically connected to the semiconductor memory device, wherein the semiconductor memory device includes: a substrate; a stack structure on the substrate, the stack structure including gate electrodes and mold insulating films, wherein the gate electrodes and the molding insulating films are alternately stacked on top of each other in a first direction intersecting an upper surface of the substrate; a channel structure extending in the first direction through the stack structure, the channel structure including a semiconductor film and a data storage film between the semiconductor film and the gate electrodes; and a high dielectric-constant film including: a first high dielectric-constant metal oxide film in contact with the data storage film; and a second high dielectric-constant metal oxide film between the first high dielectric-constant metal oxide film and at least one of the gate electrodes, wherein the data storage film includes a tunnel insulating film, a charge storage film, and a blocking insulating film sequentially disposed on the semiconductor film, wherein the blocking insulating film is between the high dielectric-constant film and the charge storage film, and wherein the first high dielectric-constant metal oxide film includes a first metal oxide doped with an impurity element.

Aspects of embodiments of the present disclosure are not limited to the above aspects, and others aspects of embodiments of the present disclosure not mentioned may be clearly understood by a person of ordinary skilled in the art from the following description.,

Specific details of other embodiments are included in the detailed description and drawings.

### BRIEF DESCRIPTION OF DRAWINGS

The above and other aspects and features of the present disclosure will become more apparent by illustrating in detail non-limiting example embodiments thereof with reference to the attached drawings, in which:

FIG. 1 is an example block diagram for illustrating a semiconductor memory device according to some embodiments of the present disclosure.

FIG. 2 is an illustrative circuit diagram for illustrating a semiconductor memory device according to some embodiments of the present disclosure.

FIG. 3 is a schematic layout diagram for illustrating a semiconductor memory device according to some embodiments of the present disclosure.

FIG. 4 is a cross-sectional view taken along a line A-A of FIG. 3.

FIG. 5 is an enlarged view for illustrating a portion R1 of FIG. 4.

FIGS. 6 and 7 are diagrams schematically illustrating a concentration of an impurity element along a line SCAN LINE of FIG. 5.

FIG. 8 is an enlarged view for illustrating a semiconductor memory device according to some embodiments of the present disclosure.

FIG. 9 is a cross-sectional view for illustrating a semiconductor memory device according to some embodiments of the present disclosure.

FIG. 10 is a cross-sectional view for illustrating a semiconductor memory device according to some embodiments of the present disclosure.

FIG. 11 is a cross-sectional view for illustrating a semiconductor memory device according to some embodiments of the present disclosure.

FIGS. 12 - 18 are diagrams illustrating intermediate structures corresponding to intermediate steps of a method for manufacturing a semiconductor memory device according to some embodiments of the present disclosure.

FIG. 19 is an example block diagram for illustrating an electronic system according to some embodiments of the present disclosure.

FIG. 20 is an example perspective view for illustrating an electronic system according to some embodiments of the present disclosure.

FIG. 21 is a schematic cross-sectional view taken along a line I-I of FIG. 20.

### DETAILED DESCRIPTIONS

Hereinafter, non-limiting example embodiments of the present disclosure will be described in detail with reference to the accompanying drawings. The same reference numerals are used for the same components in the drawings, and redundant descriptions thereof may be omitted.

As used herein, although the terms such as “first,” “second,” “upper,” and “lower” are used to describe various elements or components, these elements or components are not limited by these terms. These terms are merely used to distinguish one element or component from another element or component. Accordingly, the first element or component mentioned below may be the second element or component within the spirit and scope of the present disclosure. Further, a lower element or component mentioned below may be an upper element or component within the spirit and scope of the present disclosure.

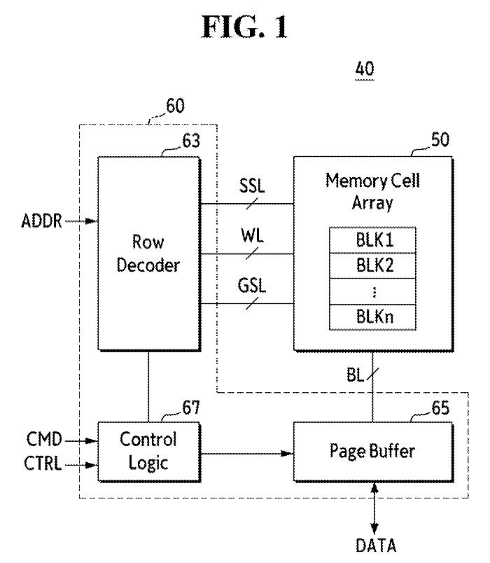

Hereinafter, a semiconductor memory device according to some embodiments will be described with reference to FIGS. 1 - 11. In the following descriptions, an example in which a semiconductor memory device according to some embodiments is embodied as a NAND flash memory device is mainly described. However, this is only an example. In another example, the semiconductor memory device according to some embodiments may be a nonvolatile memory device such as a phase-change random access memory (PRAM), a magneto-resistive random access memory (MRAM), a ferroelectric random access memory (FeRAM), or a resistive random access memory (RRAM), or a volatile memory device such as a dynamic random access memory (DRAM) or a static random access memory (SRAM).

FIG. 1 is an example block diagram for illustrating a semiconductor memory device according to some embodiments of the present disclosure.

Referring to FIG. 1, a semiconductor memory device 40 according to some embodiments of the present disclosure may include a memory cell array 50.

The memory cell array 50 may include a plurality of memory cell blocks BLK1 to BLKn. Each of the memory cell blocks BLK1 to BLKn may include a plurality of memory cells. The memory cell array 50 may be connected to a peripheral circuit 60 via a bit-line BL, a word-line WL, at least one string select line SSL, and at least one ground select line GSL. Specifically, the memory cell blocks BLK1 to BLKn may be connected to a row decoder 63 via the word-line WL, the string select line SSL, and the ground select line GSL. Further, the memory cell blocks BLK1 to BLKn may be connected to a page buffer 65 via the bit-line BL.

The peripheral circuit 60 may receive an address ADDR, a command CMD, and a control signal CTRL from an external device to the semiconductor memory device 40, and may transmit and receive data to and from an external device to the semiconductor memory device 40. The peripheral circuit 60 may include a control logic 67, the row decoder 63, and the page buffer 65. According to some embodiments, the peripheral circuit 60 may further include various sub-circuits such as an input/output circuit, a voltage generation circuit for generating various voltages for an operation of the semiconductor memory device 40, and/or an error correction circuit for correcting an error of the data DATA read from the memory cell array 50.

The control logic 67 may be connected to the row decoder 63, the input/output circuit, and the voltage generation circuit. The control logic 67 may control overall operations of the semiconductor memory device 40. The control logic 67 may generate various internal control signals used in the semiconductor memory device 40 in response to the control signal CTRL. For example, the control logic 67 may adjust a voltage level of a voltage supplied to the word-line WL and the bit-line BL when performing a memory operation such as a program operation or an erase operation.

The row decoder 63 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 63 may transmit a voltage for performing a memory operation to the word-line WL of the selected at least one memory cell block BLK1 to BLKn.

The page buffer 65 may be connected to the memory cell array 50 via the bit-line BL. The page buffer 65 may operate as a writer driver or a sense amplifier. Specifically, when performing a program operation, the page buffer 65 may operate as the writer driver to apply a voltage based on the data DATA to be stored in the memory cell array 50 to the bit-line BL. On the other hand, when performing a read operation, the page buffer 65 may operate as the sense amplifier to detect the data DATA stored in the memory cell array 50.

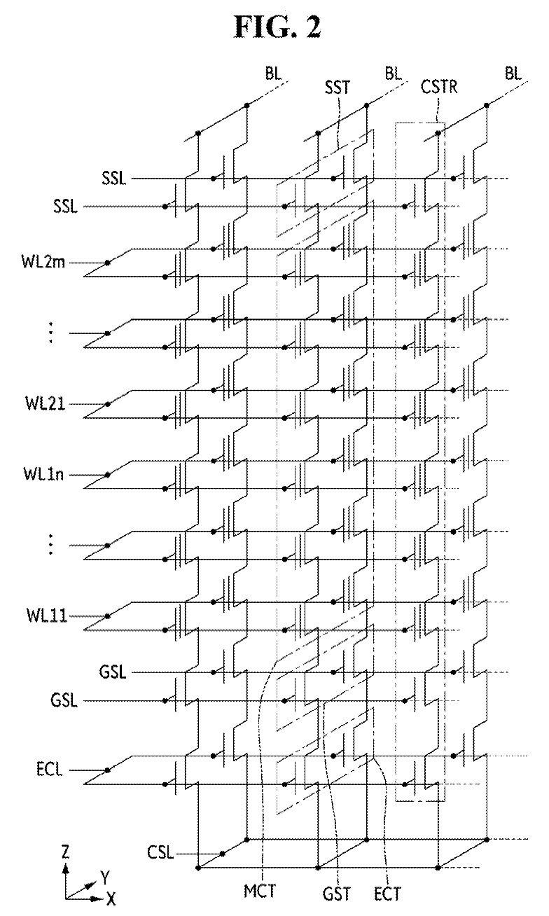

FIG. 2 is an illustrative circuit diagram for illustrating a semiconductor memory device according to some embodiments.

Referring to FIG. 2, the memory cell array (e.g., the memory cell array 50 in FIG. 1) of a semiconductor memory device according to some embodiments of the present disclosure may include a common source line CSL, a plurality of bit-lines BL, and a plurality of cell strings CSTR.

The plurality of bit lines BL may be two-dimensionally arranged in a plane including a first direction X and a second direction Y. For example, each of the bit lines BL may extend in the second direction Y and the bit lines BL may be spaced apart from each other and may be arranged along the first direction X. The plurality of cell strings CSTR may be connected in parallel to each of the bit lines BL. The cell strings CSTR may be connected in common to the common source line CSL. That is, the plurality of cell strings CSTR may be disposed between the bit lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other in a vertical direction (hereinafter, referred to as a third direction Z) intersecting the first direction X and the second direction Y.

The common source line CSL may be commonly connected to sources of the ground select transistors GST. Further, a ground select line GSL, a plurality of word-lines WL11 to WL1n and a string select line SSL may be disposed between the common source line CSL and the bit-line BL. The ground select line GSL may act as a gate electrode of the ground select transistor GST. The word-lines WL11 to WL1n may be respectively used as gate electrodes of the memory cell transistors MCT. The string select line SSL may act as a cell gate electrode of the string select transistor SST.

In some embodiments of the present disclosure, an erase control transistor ECT may be disposed between the common source line CSL and the ground select transistor GST. The common source line CSL may be commonly connected to sources of the erase control transistors ECT. Further, an erase control line ECL may be disposed between the common source line CSL and the ground select line GSL. The erase control line ECL may act as a cell gate electrode of the erase control transistor ECT. The erase control transistors ECT may generate gate induced drain leakage (GIDL) to execute an erase operation of the memory cell array.

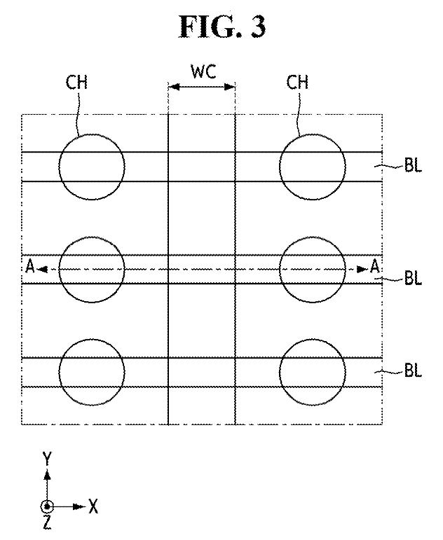

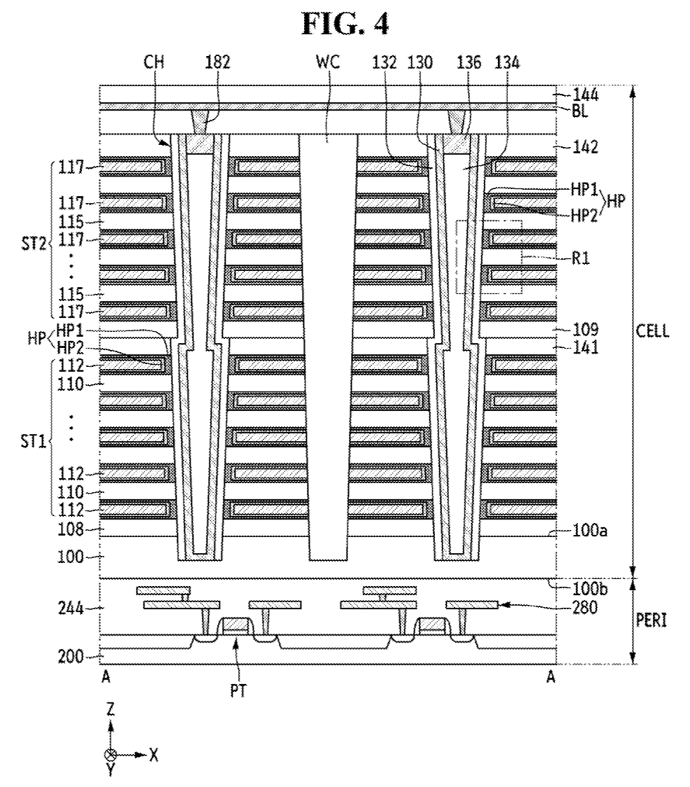

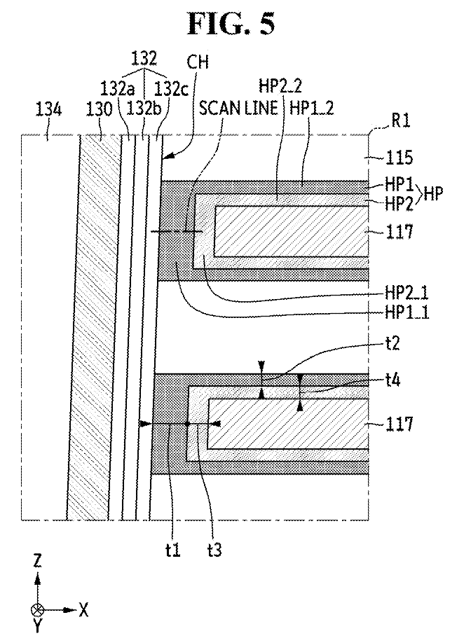

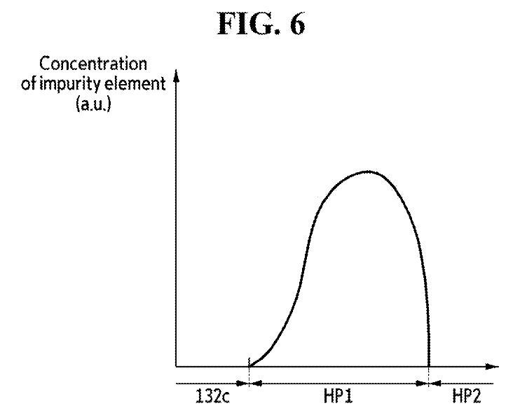

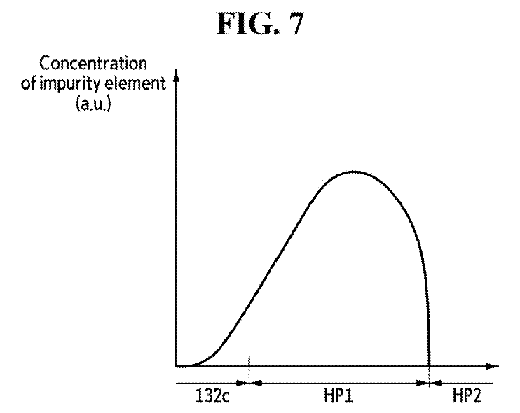

FIG. 3 is a schematic layout diagram for illustrating a semiconductor memory device according to some embodiments of the present disclosure. FIG. 4 is a cross-sectional view taken along a line A-A of FIG. 3. FIG. 5 is an enlarged view for illustrating a portion R1 of FIG. 4. FIGS. 6 and 7 are diagrams schematically illustrating a concentration of an impurity element along a line SCAN LINE of FIG. 5.

Referring to FIGS. 3 - 7, the semiconductor memory device according to some embodiments of the present disclosure may include a memory cell structure CELL and a peripheral circuit structure PERI.

The memory cell structure CELL may include a cell array area, an extension area, and an outer area.

A memory cell array (e.g., the memory cell array 50 of FIG. 1) including a plurality of memory cells may be formed in the cell array area. For example, a channel structure CH, gate electrodes (e.g., first gate electrodes 112 and second gate electrodes 117), a high dielectric-constant film HP, a bit line BL, and a cell substrate 100, which will be described later, may be disposed in the cell array area. The extension area may be disposed around the cell array area. The first gate electrodes 112 and the second gate electrodes 117 to be described later may be stacked in a stepwise manner in the extension area. The outer area may be a peripheral area surrounding the cell array area and the extension area.

The memory cell structure CELL may include the cell substrate 100, a first base insulating film 108, a first stack structure ST1, a first interlayer insulating film 141, a second base insulating film 109, a second stack structure ST2, a second interlayer insulating film 142, the high dielectric-constant film HP, the channel structure CH, a cutting pattern WC, a first inter-wiring insulating film 144, the bit line BL, and a bit line contact 182.

The cell substrate 100 may include a first surface 100a and a second surface 100b opposite to each other. Each of the first surface 100a and the second surface 100b of the cell substrate 100 may extend along a horizontal plane (e.g., an X-Y plane). In the following description, the first surface 100a may also be referred to as a front side or surface of the cell substrate 100, and the second surface 100b may also be referred to as a back or rear side or surface of the cell substrate 100.

The first direction X and the second direction Y may intersect each other. The first direction X and the second direction Y may mean directions in which the first surface 100a and the second surface 100b of the cell substrate 100 extend. The third direction Z may intersect the first direction X and the second direction Y. For example, the third direction Z may be orthogonal to the first direction X and the second direction Y.

The cell substrate 100 may include, for example, a semiconductor substrate such as a silicon substrate, a germanium substrate, or a silicon-germanium substrate. Alternatively, the cell substrate 100 may include a Silicon-On-Insulator (SOI) substrate or a Germanium-On-Insulator (GOI) substrate.

In some embodiments of the present disclosure, the cell substrate 100 may include a conductive film. The conductive film may include, for example, impurity-doped polysilicon, a metal, or a metal silicide. The conductive film may be composed of a single layer or may be composed of multiple layers. For example, the cell substrate 100 may be a n-type semiconductor substrate including n-type impurities (e.g., phosphorus (P), arsenic (As), etc.). In another example, the cell substrate 100 may include a first conductive film including a metal silicide such as tungsten silicide (WSi) and a second conductive film stacked on the first conductive film and including doped polysilicon. The cell substrate 100 may be provided as a common source line (e.g., a common source line CSL of FIG. 2) of the semiconductor device according to some embodiments.

The first base insulating film 108 may be disposed on the cell substrate 100. For example, the first base insulating film 108 may be disposed on the first surface 100a of the cell substrate 100.

The first base insulating film 108 may constitute an insulating area across the cell array area and the extension area. The first base insulating film 108 may include, for example, at least one from among silicon oxide, silicon nitride, and silicon oxynitride. However, embodiments of the present disclosure are not limited thereto. For example, the first base insulating film 108 may include a silicon oxide film.

The first base insulating film 108 may include a first surface and a second surface opposite to each other. Each of the first surface and the second surface of the first base insulating film 108 may extend along the horizontal plane (e.g., an X-Y plane). For example, the second surface of the first base insulating film 108 may be in contact with the first surface 100a of the cell substrate 100.

The first stack structure ST1 may be formed on the first surface of the first base insulating film 108. The first stack structure ST1 may include a plurality of first mold insulating films 110 and a plurality of first gate electrodes 112 which are alternately stacked on top of each other while being disposed on the first base insulating film 108. In other words, the first stack structure ST1 may include the plurality of first mold insulating films 110 and the plurality of first gate electrodes 112 which are alternately stacked on top of each other in the third direction Z perpendicularly intersecting the upper surface (e.g., the first surface 100a) of the cell substrate 100. Each of the first mold insulating films 110 and each of the first gate electrodes 112 may have a layered structure extending along the horizontal plane (e.g., an X-Y plane). The first gate electrodes 112 may be sequentially stacked and may be spaced apart from each other via each of the first mold insulating films 110.

The first gate electrodes 112 of the extension area may be stacked in a stepped manner on the first base insulating film 108. For example, in the extension area, respective lengths by which the first gate electrodes 112 extend in the horizontal direction (e.g., the first direction X or the second direction Y), respectively, may sequentially decrease as respective spacings between the first gate electrodes 112 and the first base insulating film 108 sequentially increase.

In some embodiments of the present disclosure, the first gate electrodes 112 may include at least one erase control line (e.g., the erase control line ECL of FIG. 2), at least one ground select line (e.g., the ground select line GSL of FIG. 2), and a plurality of first word lines (e.g., the word lines WL11 to WL1n of FIG. 2) which are sequentially stacked on the cell substrate 100. The numbers and shapes of the first mold insulating films 110 and the first gate electrodes 112 are only examples, and are not limited thereto.

In some embodiments, a plurality of the high dielectric-constant film HP may be disposed in the first stack structure ST1, and each of the high dielectric-constant films HP may be disposed between adjacent ones of the first mold insulating films 110. For example, the high dielectric-constant films HP may be disposed at a same level as a level of the first gate electrodes 112, respectively. A detailed description of the high dielectric-constant film HP will be set forth later.

The first interlayer insulating film 141 may be formed on the first base insulating film 108 and the first stack structure SS1. The first interlayer insulating film 141 may cover the first base insulating film 108 and the first stack structure SS1. The first interlayer insulating film 141 may include, for example, at least one from among silicon oxide, silicon oxynitride, and a low-k material having a lower dielectric constant than a dielectric constant of silicon oxide. However, embodiments of the present disclosure are not limited thereto.

The second base insulating film 109 may be formed on the first interlayer insulating film 141. The second base insulating film 109 may include, for example, at least one from among silicon oxide, silicon nitride, and silicon oxynitride. However, embodiments of the present disclosure are not limited thereto. For example, the second base insulating film 109 may include a silicon oxide film.

The second stack structure ST2 may be formed on the second base insulating film 109. The second stack structure ST2 may include a plurality of second mold insulating films 115 and a plurality of second gate electrodes 117 which are alternately stacked on top of each other while being disposed on the second base insulating film 109. Each of the second mold insulating films 115 and each of the second gate electrodes 117 may have a layered structure extending along the horizontal plane (e.g., an X-Y plane). The second gate electrodes 117 may be sequentially stacked and may be spaced apart from each other via each of the second mold insulating films 115.

The second gate electrodes 117 of the extension area may be stacked in a stepwise manner on the second base insulating film 109. For example, in the extension area, respective lengths by which the second gate electrodes 117 extend in the horizontal direction (e.g., the first direction X or the second direction Y), respectively, may sequentially decrease as respective spacings between second gate electrodes 117 and the second base insulating film 109 sequentially increase.

In some embodiments of the present disclosure, the second gate electrodes 117 may include a plurality of second word lines (e.g., the word lines WL21 to WL2m of FIG. 2) and at least one string select line (e.g., the string select line SSL of FIG. 2) which are sequentially stacked on the first stack structure ST1. The numbers and shapes of the second mold insulating films 115 and the second gate electrodes 117 are only examples, and are not limited thereto.

In some embodiments, a plurality of the high dielectric-constant film HP may be disposed in the second stack structure ST2, and each of the high dielectric-constant films HP may be disposed between adjacent ones of the second mold insulating films 115. For example, the high dielectric-constant films HP may be disposed at a same level as a level of the second gate electrodes 117, respectively.

The high dielectric-constant film HP may be disposed between the channel structure CH, each of the gate electrodes (e.g., the first gate electrodes 112 and the second gate electrodes 117), and each of the first mold insulating films 110 and the second mold insulating films 115. For example, the high dielectric-constant film HP may include a portion disposed between the channel structure CH and each of the gate electrodes (e.g., the first gate electrodes 112 and the second gate electrodes 117) and a portion disposed between each of the gate electrodes (e.g., the first gate electrodes 112 and the second gate electrodes 117) and each of the first mold insulating films 110 and the second mold insulating films 115 adjacent thereto.

In some embodiments of the present disclosure, the high dielectric-constant film HP may include a first high dielectric-constant metal oxide film HP1 and a second high dielectric-constant metal oxide film HP2.

The first high dielectric-constant metal oxide film HP1 may be in contact with the channel structure CH. For example, the first high dielectric-constant metal oxide film HP1 may be in contact with a data storage film 132 of the channel structure CH, which will be described later. The first high dielectric-constant metal oxide film HP1 may be in contact with the first mold insulating films 110, the second mold insulating films 115, the second high dielectric-constant metal oxide film HP2, and the cutting pattern WC to be described later. In some embodiments, the first high dielectric-constant metal oxide film HP1 may be spaced apart from each of the gate electrodes (e.g., the first gate electrodes 112 and the second gate electrodes 117).

The first high dielectric-constant metal oxide film HP1 may extend along an upper or lower surface of each of the first mold insulating films 110, the second mold insulating films 115, and an outer side surface of the channel structure CH. The first high dielectric-constant metal oxide films HP1 may be arranged in a symmetrical manner around the cutting pattern WC to be described later in the cross-sectional view of FIG. 4.

The second high dielectric-constant metal oxide film HP2 may be in contact with the first high dielectric-constant metal oxide film HP1 and each of the gate electrodes (e.g., the first gate electrodes 112 and the second gate electrodes 117). The second high dielectric-constant metal oxide film HP2 may be in contact with the cutting pattern WC to be described later.

The second high dielectric-constant metal oxide film HP2 may be interposed between the first high dielectric-constant metal oxide film HP1 and each of the gate electrodes (e.g., the first gate electrodes 112 and the second gate electrodes 117). The second high dielectric-constant metal oxide film HP2 may be disposed between the first high dielectric-constant metal oxide film HP1 and each of the gate electrodes (e.g., the first gate electrodes 112 and the second gate electrodes 117). The second high dielectric-constant metal oxide films HP2 may be arranged in a symmetrical manner around the cutting pattern WC to be described later with reference to the cross-sectional view of FIG. 4.

The first high dielectric-constant metal oxide film HP1 may include a first portion HP1_1 and a second portion HP1_2. The first portion HP1_1 of the first high dielectric-constant metal oxide films HP1 may be disposed between the channel structure CH and each of the gate electrodes (e.g., the first gate electrodes 112 and the second gate electrodes 117). The second portion HP1_2 of the first high dielectric-constant metal oxide films HP1 may be disposed between each of the gate electrodes (e.g., the first gate electrodes 112 and the second gate electrodes 117) and each of the first mold insulating films 110 and the second mold insulating films 115 adjacent to each of the gate electrodes (e.g., the first gate electrodes 112 and the second gate electrodes 117). For example, the second portion HP1_2 of the first high dielectric-constant metal oxide film HP1 may extend along the plane including the first direction X and the second direction Y.

The second high dielectric-constant metal oxide film HP2 may include a first portion HP2_1 and a second portion HP2_2 of the second high dielectric-constant metal oxide film HP2. The first portion HP2_1 of the second high dielectric-constant metal oxide films HP2 may be disposed between each of the gate electrodes (e.g., the first gate electrodes 112 and the second gate electrodes 117) and the first portion HP1_1 of the first high dielectric-constant metal oxide film HP1. The second portion HP2_2 of the second high dielectric-constant metal oxide films HP2 may be disposed between each of the gate electrodes (e.g., the first gate electrodes 112 and the second gate electrodes 117) and the second portion HP1_2 of the first high dielectric-constant metal oxide film HP1. For example, the second portion HP2_2 of the second high dielectric-constant metal oxide film HP2 may extend along the plane including the first direction X and the second direction Y.

In FIG. 5, a thickness t1 of the first portion HP1_1 of the first high dielectric-constant metal oxide film HP1 in the first direction X may be greater than a thicknesst2 of the second portion HP1_2 of the first high dielectric-constant metal oxide film HP1 in the third direction Z. A thickness t3 of the first portion HP2_1 of the second high dielectric-constant metal oxide film HP2 in the first direction X may be greater than a thickness t4 of the second portion HP2_2 of the second high dielectric-constant metal oxide film HP2 in the third direction Z.

In addition, the thickness t1 in the first direction X of the first portion HP1_1 of the first high dielectric-constant metal oxide film HP1 may be greater than the thickness t3 in the first direction X of the first portion HP2_1 of the second high dielectric-constant metal oxide film HP2. For example, the thickness t1 in the first direction X of the first portion HP1_1 of the first high dielectric-constant metal oxide film HP1 may be in a range of 10 to 100 times of the thickness t3 in the first direction X of the first portion HP2_1 of the second high dielectric-constant metal oxide film HP2.

In some embodiments of the present disclosure, the first high dielectric-constant metal oxide film HP1 may include a first metal oxide. The first metal oxide may include, for example, one from among hafnium oxide (HfO) and hafnium-zirconium oxide (HZO). However, embodiments of the present disclosure are not limited thereto.

The second high dielectric-constant metal oxide film HP2 may include a second metal oxide. The second metal oxide may be different from the first metal oxide. The second metal oxide may include, for example, aluminum oxide (AlO). However, embodiments of the present disclosure are not limited thereto.

The first metal oxide of the first high dielectric-constant metal oxide film HP1 may be doped with an impurity element. The impurity element doped into the first high dielectric-constant metal oxide film HP1 may include, for example, at least one from among germanium (Ge), indium (In), and gallium (Ga). A concentration of the impurity element doped into the first high dielectric-constant metal oxide film HP1 may be in a range of 1 at% inclusive to 50 at% inclusive. In some embodiments, the impurity element may not be contained in the second metal oxide of the second high dielectric-constant metal oxide film HP2.

With reference to FIGS. 6 and 7, the second high dielectric-constant metal oxide film HP2 may not contain the impurity element.

In FIG. 6, a blocking insulating film 132c of the channel structure CH, which will be described later, may not contain the impurity element doped into the first high dielectric-constant metal oxide film HP1.

In some embodiments, as illustrated in FIG. 7, the blocking insulating film 132c may contain the impurity element doped into the first high dielectric-constant metal oxide film HP1. The impurity element contained in the blocking insulating film 132c may be injected into the blocking insulating film 132c while the impurity element is injected into the first high dielectric-constant metal oxide film HP1. A concentration of the impurity element in the blocking insulating film 132c may decrease as the blocking insulating film 132c extends away from the first high dielectric-constant metal oxide film HP1.

In the semiconductor memory device, it may be important in terms of device reliability that the electrons trapped in a charge storage film 132b do not leak out thereof and are stably stored in the charge storage film 132b. To this end, a high dielectric-constant material may be disposed between each of the gate electrodes (e.g., the first gate electrodes 112 and the second gate electrodes 117) and the channel structure CH.

In the semiconductor memory device according to some embodiments of the present disclosure, the first high dielectric-constant metal oxide film HP1 of the high dielectric-constant film HP may include the metal oxide (e.g., hafnium oxide (HfO)) doped with the impurity element (e.g., germanium (Ge)). Thus, the trapped electrons may be more stably stored in the charge storage film 132b than in the metal oxide into which the impurity element is not doped. Accordingly, the semiconductor memory device with improved yield and reliability may be provided.

The second interlayer insulating film 142 may be formed on the second base insulating film 109 and the second stack structure ST2. The second interlayer insulating film 142 may cover the second base insulating film 109 and the second stack structure ST2. The second interlayer insulating film 142 may include, for example, at least one from among silicon oxide, silicon oxynitride, and a low-k material having a lower dielectric constant than a dielectric constant of silicon oxide. However, embodiments of the present disclosure are not limited thereto.

Each of the gate electrodes (e.g., the first gate electrodes 112 and the second gate electrodes 117) may include a conductive material such as, for example, a metal such as tungsten (W), molybdenum (Mo), ruthenium (Ru), cobalt (Co), nickel (Ni), or the like, or a semiconductor material such as silicon. However, embodiments of the present disclosure are not limited thereto. In some embodiments of the present disclosure, each of the gate electrodes (e.g., the first gate electrodes 112 and the second gate electrodes 117) may include molybdenum (Mo).

Each of the first mold insulating films 110 and the second mold insulating films 115 may include, for example, but is not limited to, at least one from among silicon oxide, silicon nitride, and silicon oxynitride. For example, each of the first mold insulating films 110 and the second mold insulating films 115 may include a silicon oxide film.

The channel structure CH may be disposed in the cell array area. Each of the channel structures CH may be disposed between the cutting patterns WC to be described later. The channel structure CH may extend in the third direction Z to extend through the first stack structure ST1 and the second stack structure ST2. The channel structure CH may extend in the third direction Z to intersect and extend through the gate electrodes (e.g., the first gate electrodes 112 and the second gate electrodes 117). For example, the channel structure CH may be a pillar-shaped (e.g., cylindrical) structure extending in the third direction Z.

In some embodiments of the present disclosure, the plurality of channel structures CH may be arranged in a zigzag manner. For example, the channel structures CH may be arranged in a staggered manner in the first direction X and the second direction Y. The channel structures CH may further improve an integration density of the semiconductor memory device. The number and arrangement of the channel structures CH are only examples, and are not limited to those shown.

In some embodiments of the present disclosure, each of the channel structures CH may have a step between the first stack structure ST1 and the second stack structure ST2. For example, as illustrated in FIG. 4, a side surfaces of each of the channel structures CH may have a bent portion at a boundary between the first interlayer insulating film 141 and the second base insulating film 109. For example, the bent portion may include a surface of the channel structure CH that extends substantially in a horizontal direction (e.g., the first direction X) and both ends of the surface may be connected to portions of the side surfaces of the channel structures CH that extend substantially in the vertical direction (e.g., the third direction Z).

Each of the channel structures CH may include a semiconductor film 130 and the data storage film 132.

The semiconductor film 130 may extend in the third direction Z so as to intersect the plurality of gate electrodes (e.g., the first gate electrodes 112 and the second gate electrodes 117). Although the semiconductor film 130 is illustrated only in a cup shape, this is only an example. For example, the semiconductor film 130 may have various shapes such as a cylindrical shape, a rectangular prism shape, a solid pillar shape, and the like. The semiconductor film 130 may include, for example, a semiconductor material such as monocrystalline silicon, polycrystalline silicon, an organic semiconductor, and a carbon nanostructure. However, embodiments of the present disclosure are not limited thereto.

The data storage film 132 may be interposed between the semiconductor film 130 and the plurality of gate electrodes (e.g., the first gate electrodes 112 and the second gate electrodes 117). For example, the data storage film 132 may extend along an outer side surface of the semiconductor film 130. The data storage film 132 may include, for example, at least one from among silicon oxide, silicon nitride, silicon oxynitride, and a high dielectric-constant material having a higher dielectric constant than a dielectric constant of silicon oxide. However, embodiments of the present disclosure are not limited thereto. The high dielectric-constant material may include, for example, at least one from among aluminum oxide, hafnium oxide, lanthanum oxide, tantalum oxide, titanium oxide, lanthanum hafnium oxide, lanthanum aluminum oxide, dysprosium scandium oxide, and combinations thereof.

In some embodiments of the present disclosure, the data storage film 132 may be constructed to have multiple films. For example, as illustrated in FIG. 5, the data storage film 132 may include a tunnel insulating film 132a, a charge storage film 132b, and the blocking insulating film 132c, which may be sequentially stacked on the outer side surface of the semiconductor film 130.

The tunnel insulating film 132a may include, for example, silicon oxide or a high dielectric-constant material (e.g., aluminum oxide (Al₂O₃) or hafnium oxide (HfO₂)) having a higher dielectric constant than a dielectric constant of silicon oxide. The charge storage film 132b may include, for example, silicon nitride. The blocking insulating film 132c may include, for example, silicon oxide or a high dielectric-constant material having a higher dielectric constant than a dielectric constant of silicon oxide.

In some embodiments, the high dielectric-constant film HP may be spaced apart from the charge storage film 132b while the blocking insulating film 132c is interposed therebetween. The first high dielectric-constant metal oxide film HP1 of the high dielectric-constant film HP may be in contact with the blocking insulating film 132c.

In some embodiments of the present disclosure, the channel structure CH may further include a filling insulating film 134. The filling insulating film 134 may be formed to fill the inside of the semiconductor film 130 having a cup shape. The filling insulating film 134 may include an insulating material such as, for example, silicon oxide. However, embodiments of the present disclosure are not limited thereto.

In some embodiments of the present disclosure, the channel structure CH may further include a channel pad 136. The channel pad 136 may be formed to contact and be connected to one end (e.g., an upper end) of the semiconductor film 130. The channel pad 136 may include a conductive material such as, for example, doped polysilicon, metal, or metal silicide. However, embodiments of the present disclosure are not limited thereto.

In some embodiments of the present disclosure, the channel structure CH may protrude downwardly beyond the first base insulating film 108. For example, as illustrated in FIG. 4, a vertical level of the other end (e.g., the lower end) of the semiconductor film 130 may be lower than the second surface (e.g., the lower end) of the first base insulating film 108.

The cutting pattern WC may be formed across the cell array area and the extension area. The cutting pattern WC may extend in an elongate manner in the second direction Y to cut each of the stack structures (e.g., the first stack structure ST1 and the second stack structure ST2). In addition, the plurality of cutting patterns WC may be spaced apart from each other in the first direction X and may extend parallel to each other in the second direction Y. Each of the stack structures (e.g., the first stack structure ST1 and the second stack structure ST2) may be divided by the plurality of cutting patterns WC into a plurality of portions respectively constituting a plurality of memory cell blocks (e.g., the memory cell blocks BLK1 to BLKn of FIG. 1). For example, two adjacent cutting patterns WC may define one memory cell block therebetween. A plurality of channel structures CH may be disposed in each of the memory cell blocks defined by two adjacent cutting patterns WC.

In some embodiments of the present disclosure, the cutting pattern WC may protrude downwardly beyond the first base insulating film 108. For example, as illustrated in FIG. 4, a vertical level of the lower end of the cutting pattern WC may be lower than the second surface (e.g., the lower end) of the first base insulating film 108.

In some embodiments of the present disclosure, the cutting pattern WC may include an insulating material such as, for example, at least one from among silicon oxide, silicon nitride, and silicon oxynitride. However, embodiments of the present disclosure are not limited thereto. For example, the cutting pattern WC may include a silicon oxide film.

A gate contact may be disposed in the extension area. The plurality of gate contacts may be electrically connected to a plurality of corresponding gate electrodes (e.g., the first gate electrodes 112 and the second gate electrodes 117), respectively. For example, each of the gate contacts GC may extend in the third direction Z to extend through the first interlayer insulating film 141 and/or the second interlayer insulating film 142, and to contact and be connected to a corresponding one of the gate electrodes (e.g., the first gate electrodes 112 and the second gate electrodes 117). In some embodiments of the present disclosure, a width of the gate contact may decrease as the gate contact extends toward each of the gate electrodes (e.g., the first gate electrodes 112 and the second gate electrodes 117). Each of a source contact and a through via may be disposed in the external area. Each of the source contact and the through via may extend in the third direction Z to extend through the first interlayer insulating film 141 and/or the second interlayer insulating film 142. In some embodiments of the present disclosure, each of a width of the source contact and the width of the through via may decrease as each of the source contact and the through via extends toward the cell substrate 100.

The first inter-wiring insulating film 144 may be disposed on the second interlayer insulating film 142. The first inter-wiring insulating film 144 may cover the cutting pattern WC, the channel structure CH, and the second interlayer insulating film 142. The first inter-wiring insulating film 144 may include, for example, at least one from among silicon oxide, silicon oxynitride, and a low-k material having a lower dielectric constant than a dielectric constant of silicon oxide. However, embodiments of the present disclosure are not limited thereto.

The cell wiring structure may be formed on the second interlayer insulating film 142. The cell wiring structure may be disposed in the first inter-wiring insulating film 144. The cell wiring structure may be electrically connected to the channel structure CH, the gate contact, the source contact, and/or the through via. The cell wiring structure may include the bit line BL and the bit line contact 182.

The bit line BL may be disposed in the first inter-wiring insulating film 144. The bit line BL may extend in an elongate manner in the first direction X. In addition, a plurality of bit lines BL may be spaced apart from each other in the second direction Y and may extend in a parallel manner to each other in the first direction X.

The bit line BL may be electrically connected to the plurality of channel structures CH arranged in the first direction X. For example, the bit line BL may be connected to one end (e.g., an upper end) of the semiconductor film 130 via the bit line contact 182 and the channel pad 136 of the channel structure CH. The bit line contact 182 may be disposed in the first inter-wiring insulating film 144 and between the bit line BL and the channel structure CH.

The cell wiring structure may include a conductive material. For example, the cell wiring structure may include at least one from among aluminum (Al), copper (Cu), tungsten (W), molybdenum (Mo), cobalt (Co), ruthenium (Ru), and alloys thereof. However, embodiments of the present disclosure are not limited thereto. For example, the cell wiring structure may include a copper (Cu) wiring.

The peripheral circuit structure PERI may include a peripheral circuit substrate 200, a peripheral circuit element PT, and a peripheral circuit wiring structure 280.

The peripheral circuit substrate 200 may include, for example, a semiconductor substrate such as a silicon substrate, a germanium substrate, or a silicon-germanium substrate. Alternatively, the peripheral circuit substrate 200 may include a Silicon-On-Insulator (SOI) substrate or a Germanium-On-Insulator (GOI) substrate.

The peripheral circuit element PT may be formed on the peripheral circuit substrate 200. The peripheral circuit element PT may constitute a peripheral circuit (e.g., the peripheral circuit 60 of FIG. 1) that controls the operation of the semiconductor memory device. For example, the peripheral circuit device PT may include a control logic (e.g., control logic 67 of FIG. 1), a row decoder (e.g., row decoder 63 of FIG. 1), a page buffer (e.g., page buffer 65 of FIG. 1), etc. In the following description, a surface of the peripheral circuit substrate 200 on which the peripheral circuit element PT is disposed may be referred to as a front side or surface of the peripheral circuit substrate 200, and a surface of the peripheral circuit substrate 200 opposite to the front surface of the peripheral circuit substrate 200 may be referred to as a back or rear side or surface of the peripheral circuit substrate 200.

The peripheral circuit element PT may include, for example, a transistor. However, embodiments of the present disclosure are not limited thereto. For example, the peripheral circuit element PT may include various passive elements such as a capacitor, a resistor, an inductor, and the like, as well as various active elements such as a transistor.

The peripheral circuit wiring structure 280 may be formed on the peripheral circuit element PT. For example, a second inter-wiring insulating film 244 may be formed on the front surface of the peripheral circuit substrate 200. The peripheral circuit wiring structure 280 may be formed in the second inter-wiring insulating film 244 and may be electrically connected to the peripheral circuit element PT. The number of layers and the arrangement of the peripheral circuit wiring structure 280 shown in the drawings are only examples, and are not limited thereto.

In some embodiments of the present disclosure, the memory cell structure CELL may be stacked on the peripheral circuit structure PERI. For example, the memory cell structure CELL may be stacked on the second inter-wiring insulating film 244.

In some embodiments of the present disclosure, the second surface of the first base insulating film 108 may face towards the peripheral circuit structure PERI. For example, the first stack structure ST1 and the second stack structure ST2 may be disposed on the peripheral circuit structure PERI.

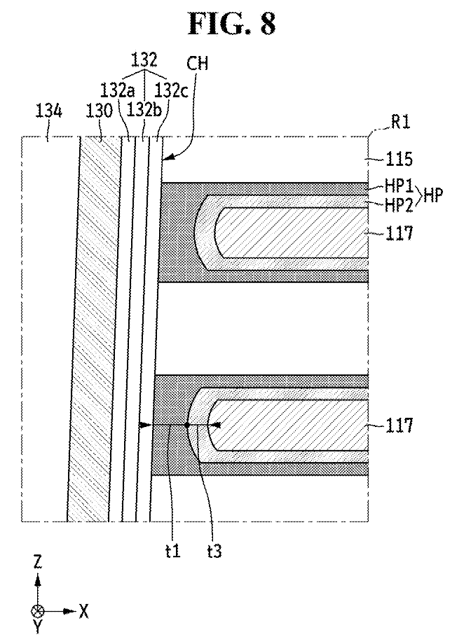

FIG. 8 is an enlarged view for illustrating a semiconductor memory device according to some embodiments of the present disclosure. For convenience of description, descriptions duplicate with the descriptions provided above with reference to FIGS. 1 - 7 may be briefly provided or may be omitted.

Referring to FIG. 8, in some embodiments of the present disclosure, a contact surface between the first high dielectric-constant metal oxide film HP1 and the second high dielectric-constant metal oxide film HP2 of the high dielectric-constant film HP may be a curved surface.

For example, the contact surface (e.g., interface) between the first high dielectric-constant metal oxide film HP1 and the second high dielectric-constant metal oxide film HP2 may have a convex shape toward the channel structure CH. In addition, the contact surface (e.g., interface) between the second high dielectric-constant metal oxide film HP2 and the gate electrode 117 may also be a curved surface having a convex shape toward the channel structure CH.

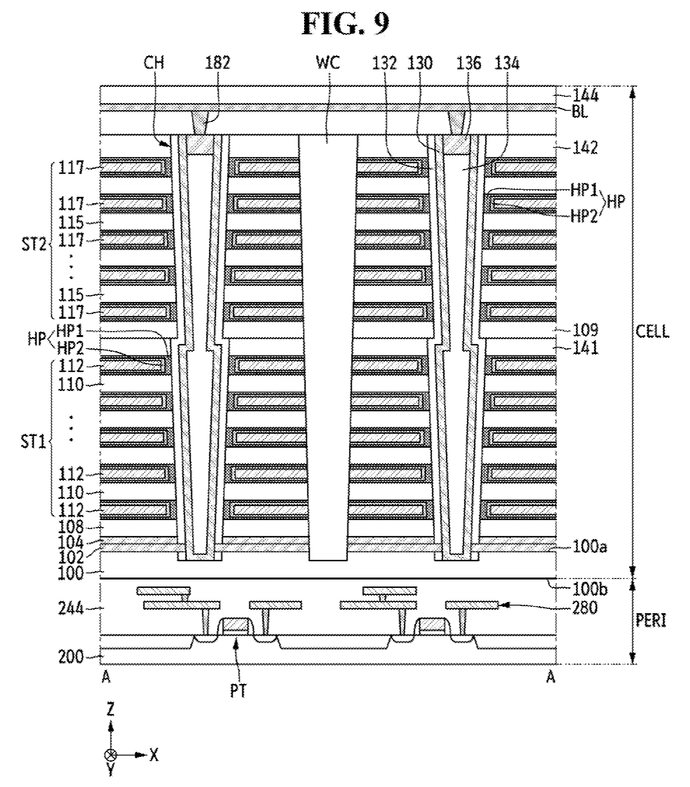

FIG. 9 is a cross-sectional view for illustrating a semiconductor memory device according to some embodiments of the present disclosure. For convenience of description, descriptions duplicate with the descriptions provided above with reference to FIGS. 1 - 7 may be briefly provided or may be omitted.

Referring to FIG. 9, the semiconductor memory device according to some embodiments of the present disclosure further includes a source layer 102 and a source support layer 104.

The source layer 102 may be formed on the first surface 100a of the cell substrate 100. The source layer 102 may be interposed between the cell substrate 100 and the stack structures (e.g., the first stack structure ST1 and the second stack structure ST2). For example, the source layer 102 may conformally extend along the first surface 100a of the cell substrate 100. The source layer 102 may be electrically connected to the semiconductor film 130. For example, the source layer 102 may extend through the data storage film 132 so as to be in contact with a side surface of the semiconductor film 130.

The source layer 102 may include a conductive material such as, for example, polysilicon doped with impurities or a metal. However, embodiments of the present disclosure are not limited thereto. A combination of the cell substrate 100 and the source layer 102 may be provided as the common source line (e.g., common source line CSL of FIG. 2) of the semiconductor memory device according to some embodiments.

A source sacrificial layer may be formed on the cell substrate 100. The source sacrificial layer may be disposed at a same level as a level of the source layer 102. As used herein, “being disposed at the same level” means disposed at the same vertical level based on the first surface 100a of the cell substrate 100. For example, a lower surface of the source sacrificial layer may be disposed at a same vertical level as a vertical level of a lower surface of the source layer 102. The source sacrificial layer may be a layer that remains after a portion of the source sacrificial layer is replaced with the source layer 102. In this case, a thickness of the source layer 102 may be equal to a thickness of the source sacrificial layer. For example, an upper surface of the source sacrificial layer may be disposed at a same vertical level as a vertical level of an upper surface of the source layer 102.

The source sacrificial layer may include an insulating material such as, for example, at least one from among silicon oxide, silicon nitride, and silicon oxynitride. However, embodiments of the present disclosure are not limited thereto. In some embodiments, the source sacrificial layer may include a material having an etch selectivity with respect to the first mold insulating films 110 and the second mold insulating films 115. For example, each of the first mold insulating films 110 and the second mold insulating films 115 may include a silicon oxide film, and the source sacrificial layer may include a silicon nitride film.

The source support layer 104 may be formed on the cell substrate 100, the source layer 102, and the source sacrificial layer. For example, the source support layer 104 may conformally extend along the upper surface of the cell substrate 100, the upper surface of the source layer 102, and the upper surface of the source sacrificial layer.

The source support layer 104 may include a material having an etch selectivity with respect to the source sacrificial layer. For example, the source sacrificial layer may include a silicon nitride film, and the source support layer 104 may include a polysilicon film. In some embodiments, a combination of the cell substrate 100, the source layer 102, and the source support layer 104 may be provided as the common source line (e.g., common source line CSL of FIG. 2) of the semiconductor device according to some embodiments.

The source support layer 104 may be used as a support for preventing collapse or fall over of a mold stack in a replacement process for forming the source layer 102. For example, the source layer 102 and/or the source sacrificial layer may not cover a portion of the first surface 100a of the cell substrate 100. According to some embodiments, a portion of the source support layer 104 may extend along an exposed portion of the first surface 100a of the cell substrate 100 so as to contact the upper surface of the cell substrate 100.

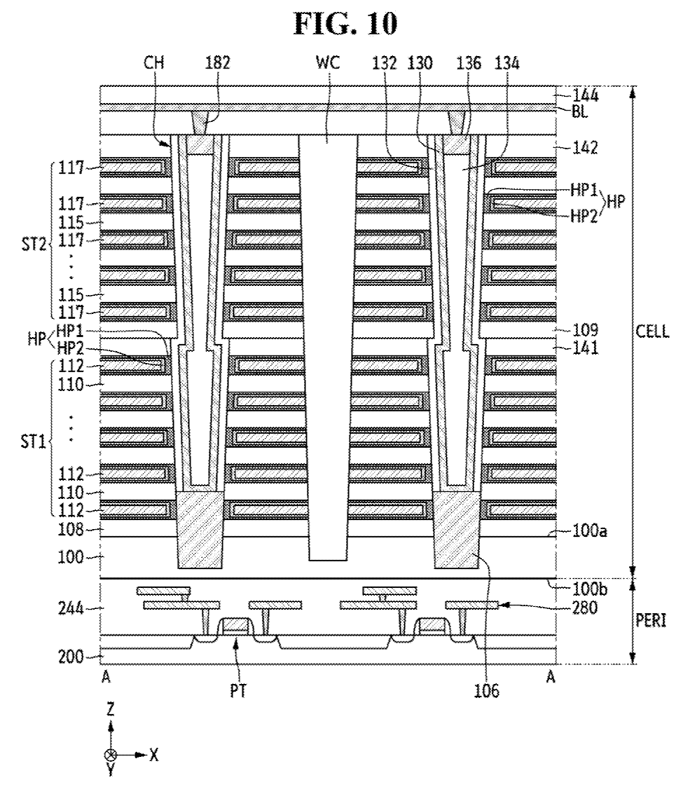

FIG. 10 is a cross-sectional view for illustrating a semiconductor memory device according to some embodiments of the present disclosure. For convenience of description, descriptions duplicate with the descriptions provided above with reference to FIGS. 1 - 7 may be briefly provided or may be omitted.

Referring to FIG. 10, in the semiconductor memory device according to some embodiments of the present disclosure, the channel structure CH further includes a source pattern 106.

The source pattern 106 may be formed on the cell substrate 100. The source pattern 106 may be interposed between the cell substrate 100 and the semiconductor film 130 and between the cell substrate 100 and the data storage film 132. The source pattern 106 may be electrically connected to the semiconductor film 130. For example, the semiconductor film 130 may extend through a lower portion of the data storage film 132 such that one end (e.g., a lower end) thereof is in contact with the source pattern 106.

The source pattern 106 may include a conductive material such as, for example, polysilicon doped with impurities or a metal. However, embodiments of the present disclosure are not limited thereto. In some embodiments, the source pattern 106 may be formed in a selective epitaxial growth process from the cell substrate 100. A combination of the cell substrate 100 and the source pattern 106 may be provided as the common source line (e.g., common source line CSL of FIG. 2) of the semiconductor device according to some embodiments.

In some embodiments of the present disclosure, the source pattern 106 may intersect the first gate electrode 112. The source pattern 106 may intersect the lowermost one of the first gate electrodes 112. For example, a vertical level of an upper surface of the source pattern 106 may be higher than a vertical level of an upper surface of the lowermost one of the first gate electrodes 112.

In some embodiments of the present disclosure, the source pattern 106 may be surrounded with the high dielectric-constant film HP. For example, the source pattern 106 may be surrounded by a lowermost one of the high dielectric-constant films HP. According to some embodiments, the source pattern 106 may be spaced apart from the high dielectric-constant film HP via a side insulating film. The side insulating film may be disposed between the source pattern 106 and the high dielectric-constant film HP.

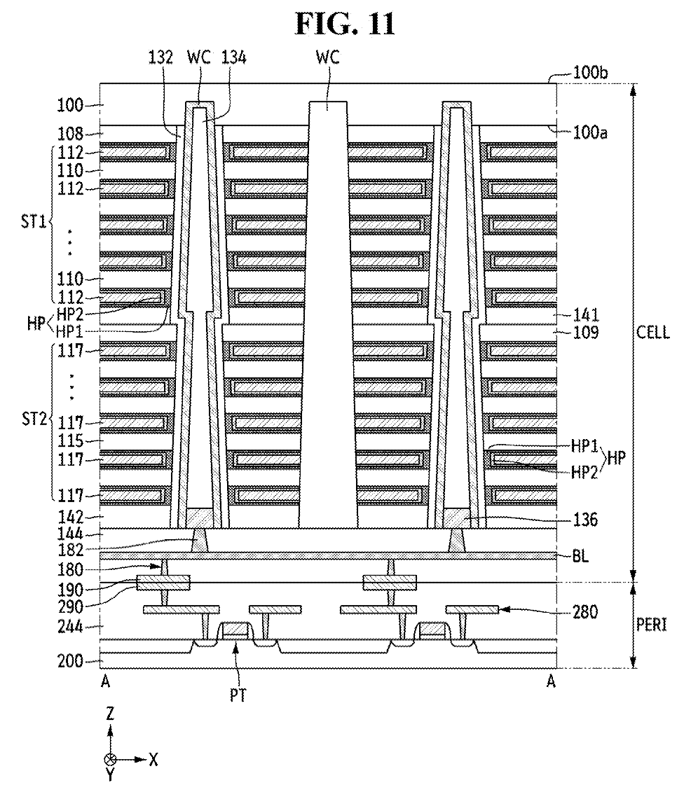

FIG. 11 is a cross-sectional view for illustrating a semiconductor memory device according to some embodiments of the present disclosure. For convenience of description, descriptions duplicate with the descriptions provided above with reference to FIGS. 1 - 7 may be briefly provided or may be omitted.

Referring to FIG. 11, in the semiconductor memory device according to some embodiments of the present disclosure, the first surface 100a of the cell substrate 100 may face towards the peripheral circuit structure PERI.

For example, the semiconductor device according to some embodiments of the present disclosure may have a chip to chip (C2C) structure. The C2C structure may mean that an upper chip including the memory cell structure CELL is fabricated on a first wafer, a lower chip including the peripheral circuit structure PERI is fabricated on a second wafer different from the first wafer, and then the upper chip and the lower chip are connected to each other in a bonding manner.

For example, the bonding manner may refer to a scheme of connecting a first bonding metal 190 formed as the uppermost metal layer of the upper chip and a second bonding metal 290 formed as the uppermost metal layer of the lower chip to each other. For example, when each of the first bonding metal 190 and the second bonding metal 290 is made of copper (Cu), the bonding scheme may be a Cu-Cu bonding scheme. However, this is merely an example, and the first bonding metal 190 and the second bonding metal 290 may be made of various other metals such as aluminum (Al) or tungsten (W).

As the first bonding metal 190 and the second bonding metal 290 are bonded to each other, the cell circuit wiring structure 180 may be electrically connected to the peripheral circuit wiring structure 280. Accordingly, the plurality of memory cells may be electrically connected to the peripheral circuit element PT.

In some embodiments of the present disclosure, the channel structure CH may protrude upwardly beyond the upper surface of the first base insulating film 108. For example, a vertical level of one end (e.g., an upper end) of the semiconductor film 130 may be higher than a vertical level of the upper surface of the first base insulating film 108. The semiconductor film 130 may have an improved contact area with the cell substrate 100 to reduce contact resistance.

In some embodiments, the peripheral circuit structure PERI, the bit line BL, the second interlayer insulating film 142, the second stack structure ST2, the second base insulating film 109, the first interlayer insulating film 141, the first stack structure ST1, the first base insulating film 108, and the cell substrate 100 may be sequentially stacked in the third direction Z.

In some embodiments of the present disclosure, the cell substrate 100 may extend along the first direction X. Unlike the illustrated example, the cell substrate 100 may conformally extend along a profile of the upper surface of the first base insulating film 108, the protruding portion of the channel structure CH, and the protruding portion of the cutting pattern WC.

Hereinafter, a method for manufacturing a semiconductor memory device according to some embodiments will be described with reference to FIGS. 1 -18.

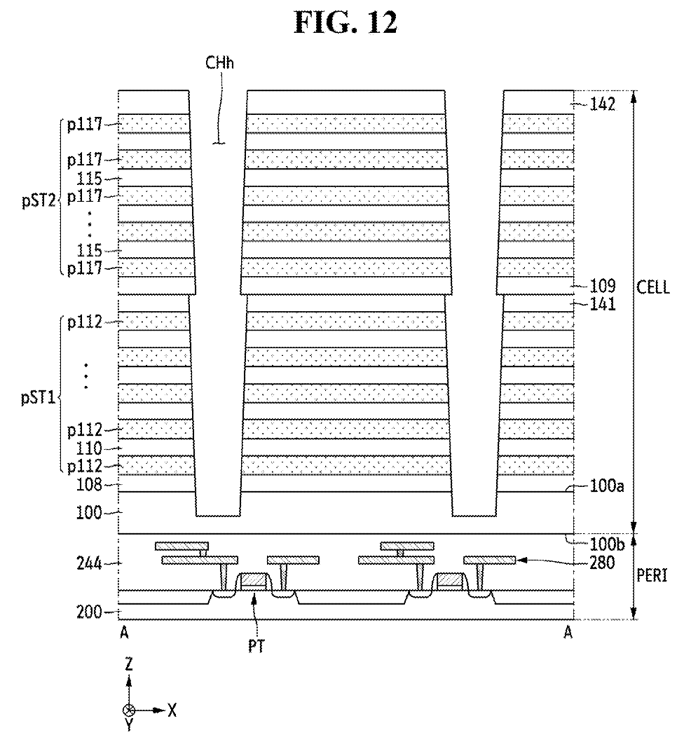

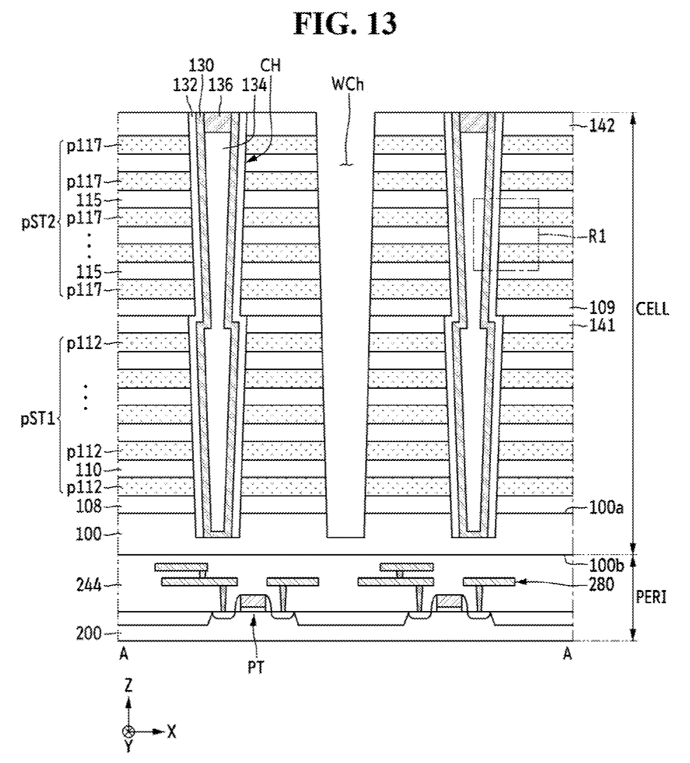

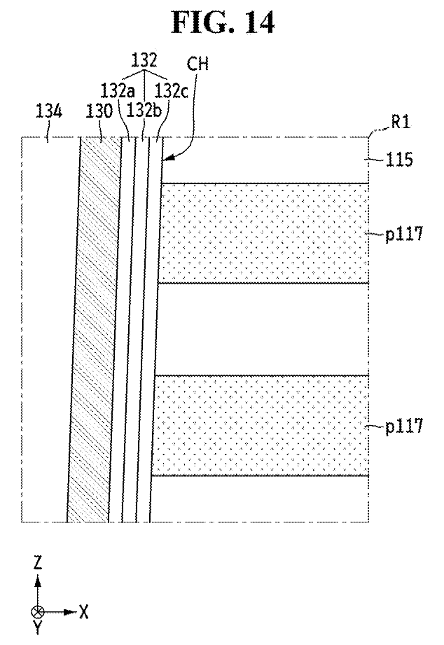

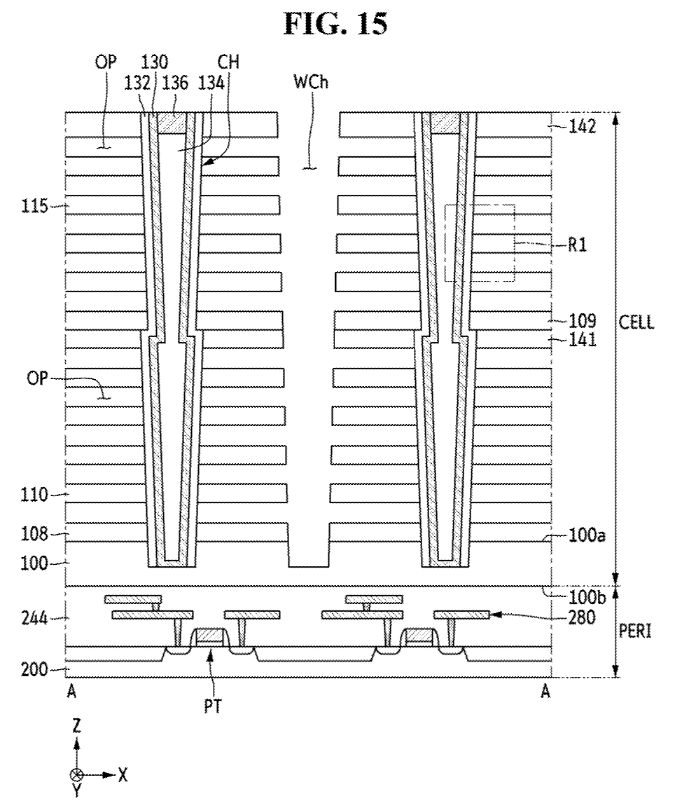

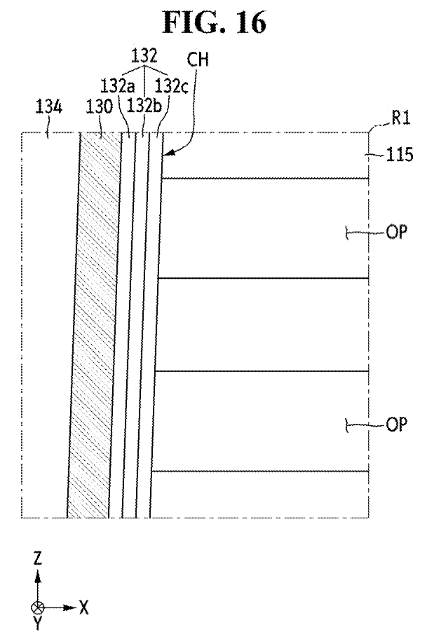

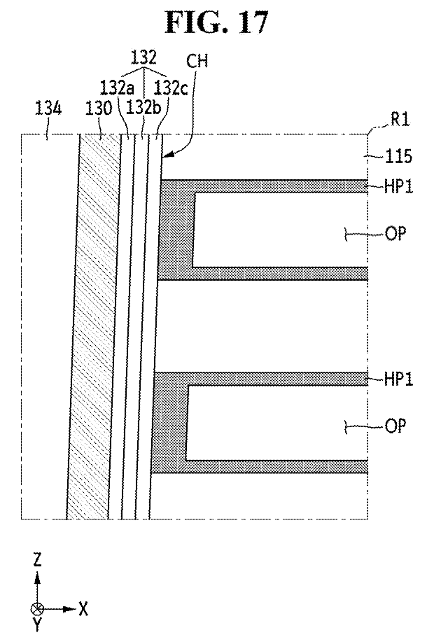

FIGS. 12- 18 are diagrams illustrating intermediate structures corresponding to intermediate steps of a method for manufacturing a semiconductor memory device according to some embodiments of the present disclosure. For convenience of description, descriptions duplicate with the descriptions provided above with reference to FIGS. 1 - 11 may be briefly provided or may be omitted.

Referring to FIG. 12, the cell substrate 100 may be formed on the peripheral circuit structure PERI.

Specifically, the cell substrate 100 may be stacked on the peripheral circuit structure PERI. For example, the peripheral circuit element PT, the peripheral circuit wiring structure 280, and the second inter-wiring insulating film 244 may be formed on the peripheral circuit substrate 200. The cell substrate 100 may be stacked on the second inter-wiring insulating film 244. The first base insulating film 108 may be stacked on the cell substrate 100.

Subsequently, the first mold insulating films 110 and first mold sacrificial films p112 may be alternately stacked on top of each other in the third direction Z, and thus a pre-first stack structure pST1 may be formed on the first base insulating film 108. The first mold sacrificial film p112 may include a material having an etch selectivity with respect to the first mold insulating film 110. For example, the first mold sacrificial film p112 may include silicon nitride, and the first mold insulating film 110 may include silicon oxide.

Subsequently, the first interlayer insulating film 141 and the second base insulating film 109 may be sequentially stacked on the pre-first stack structure pST1. Thereafter, a pre-second stack structure pST2 may be stacked on the second base insulating film 109. A description of a process of forming the pre-second stack structure pST2 may be replaced with the above description of the process of forming the pre-first stack structure pST1. Subsequently, the second interlayer insulating film 142 may be stacked on the pre-second stack structure pST2.

Subsequently, at least one channel hole CHh may be formed in the first pre-stack structure pST1 and the second pre-stack structure pST2. The channel hole CHh may extend through the first pre-stack structure pST1 and the second pre-stack structure pST2 in the third direction Z. The channel hole CHh may have a step at a boundary between the pre-first stack structure pST1 and the pre-second stack structure pST2. The channel hole CHh may expose a portion of the cell substrate 100 in the third direction Z.

Next, referring to FIGS. 13 and 14, the channel structure CH may be formed in the channel hole CHh. For reference, FIG. 14 is an enlarged view of a portion R1 of FIG. 13.

Specifically, the data storage film 132, the semiconductor film 130, and the filling insulating film 134 may fill the channel hole CHh of FIG. 12. A lower end of the semiconductor film 130 may be in contact with the cell substrate 100. Thereafter, the channel pad 136 may be formed.

Subsequently, a cutting area WCh may be formed. The cutting area WCh may extend in the second direction Y to cut the first pre-stacked structure pST1 and the second pre-stacked structure pST2. Portions of the first mold sacrificial films p112 and the second mold sacrificial films p117 may be exposed through the cutting area WCh.

Subsequently, referring to FIGS. 15 and 16, the first mold sacrificial films p112 and the second mold sacrificial films p117 exposed through the cutting area WCh may be selectively removed.

As a result, openings OP may be formed in a space in which the first mold sacrificial films p112 and the second mold sacrificial films p117 have been removed. Specifically, the blocking insulating film 132c of the channel structure CH may be exposed through the openings OP.

Subsequently, referring to FIG. 17, the first high dielectric-constant metal oxide film HP1 may be formed to fill a portion of the openings OP.

Specifically, the first metal oxide may be formed in the openings OP. The first metal oxide may include, for example, one from among hafnium oxide (HfO) and hafnium-zirconium oxide (HZO). However, embodiments of the present disclosure are not limited thereto. Subsequently, impurity element doping may be performed into the first metal oxide. The impurity element may include, for example, at least one from among germanium (Ge), indium (In), and gallium (Ga). However, embodiments of the present disclosure are not limited thereto. A method of doping the impurity element may be a method of doping the impurity element using ion implantation. However, embodiments of the present disclosure are not limited thereto. For example, the first metal oxide as a precursor and the impurity element may be simultaneously deposited into the opening OP.

Subsequently, referring to FIG. 18, the second high dielectric-constant metal oxide film HP2 may be formed to fill a partial space in the openings OP.

Specifically, the second metal oxide may be formed in the openings OP. The second metal oxide may be, for example, aluminum oxide (AlO). However, embodiments of the present disclosure are not limited thereto.

Subsequently, referring to FIG. 4, the gate electrodes (e.g., the first gate electrodes 112 and the second gate electrodes 117) filling the remaining space of the openings OP may be formed in place of the removed first mold sacrificial films p112 and second mold sacrificial films p117. Subsequently, the cutting pattern WC, the bit line BL, and the first inter-wiring insulating film 144 may be formed. Accordingly, the semiconductor memory device according to some embodiments of the present disclosure as described with reference to FIGS. 1 - 7 may be provided.

Hereinafter, an electronic system including a semiconductor memory device according to some embodiments will be described with reference to FIGS. 1 -21.

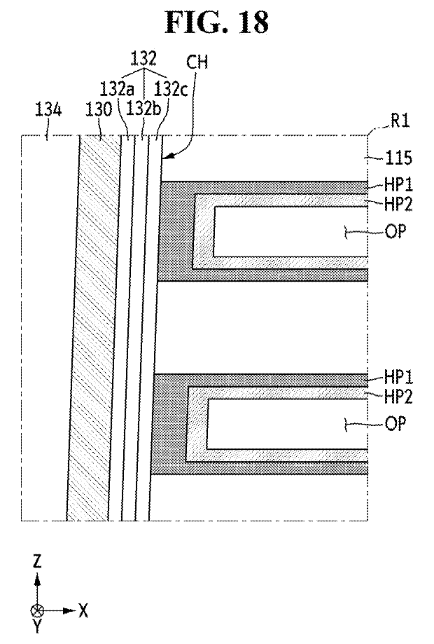

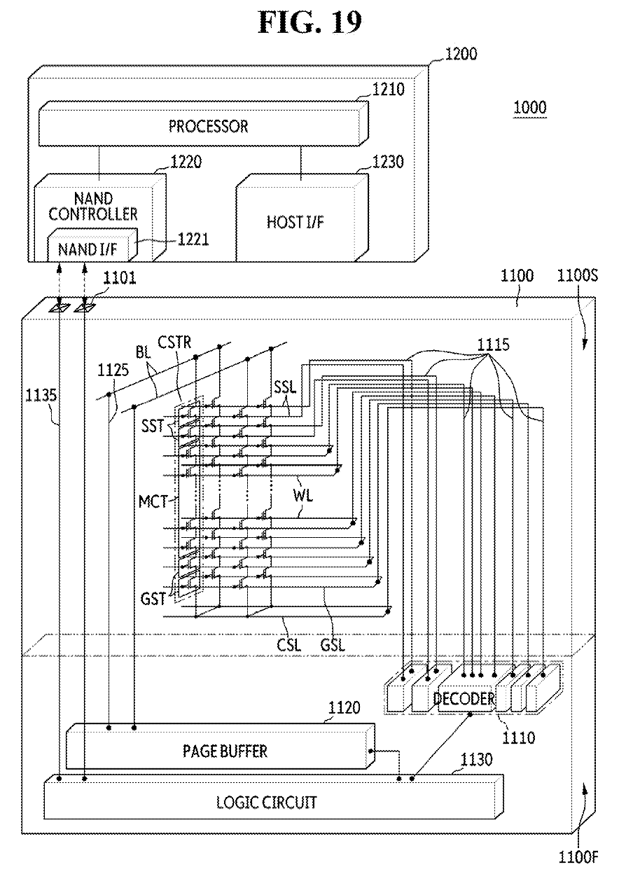

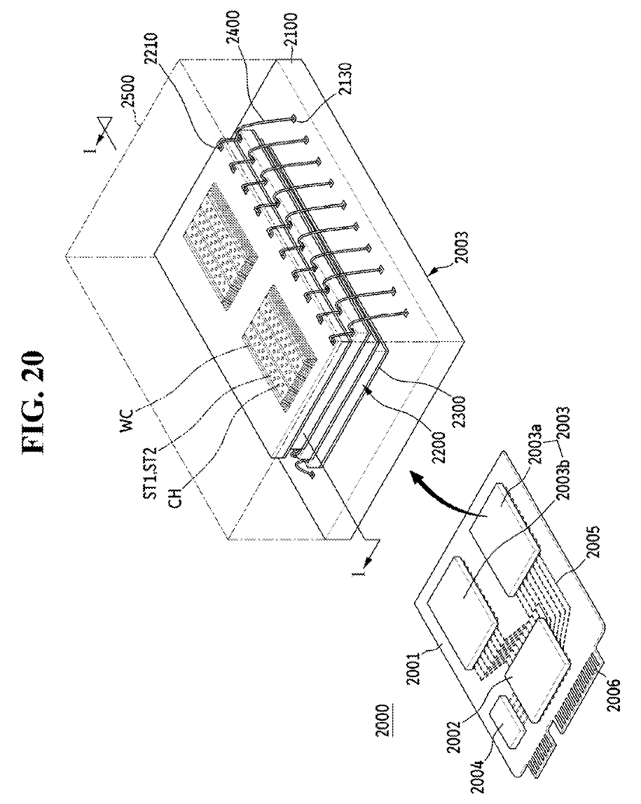

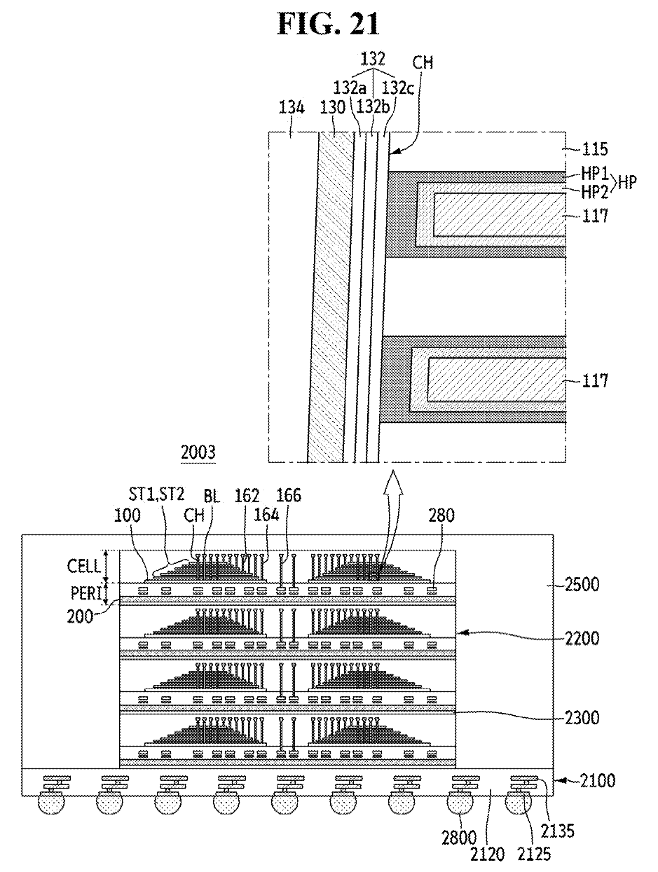

FIG. 19 is an example block diagram for illustrating an electronic system according to some embodiments of the present disclosure. FIG. 20 is an example perspective view for illustrating an electronic system according to some embodiments of the present disclosure. FIG. 21 is a schematic cross-sectional view taken along a line I-I of FIG. 20. For convenience of description, descriptions duplicate with the descriptions provided above with reference to FIGS. 1 - 18 may be briefly provided or may be omitted.

Referring to FIG. 19, an electronic system 1000 according to some embodiments of the present disclosure may include a semiconductor memory device 1100 and a controller 1200 electrically connected to the semiconductor memory device 1100.

The electronic system 1000 may be a storage device including one or a plurality of semiconductor memory devices 1100 or an electronic device including the storage device. For example, the electronic system 1000 may be embodied as a solid state drive device (SSD), a Universal Serial Bus (USB), a computing system, a medical device, or a communication device including one or a plurality of semiconductor memory devices 1100.

The semiconductor memory device 1100 may be embodied as, for example, a non-volatile memory device (e.g., a NAND flash memory device) and may include, for example, at least one of the semiconductor memory devices as described above with reference to FIGS. 1 -11. The semiconductor memory device 1100 may include a first structure 1100F and a second structure 1100S on the first structure 1100F.

The first structure 1100F may be a peripheral circuit structure including a decoder circuit 1110 (e.g., the row decoder 63 in FIG. 1), a page buffer 1120 (e.g., the page buffer 65 in FIG. 1), and a logic circuit 1130 (e.g., the control logic 67 of FIG. 1). The first structure 1100F may correspond to, for example, the peripheral circuit structure PERI as described above with reference to FIGS. 1 - 11.

The second structure 1100S may include the common source line CSL, the plurality of bit-lines BL, and the plurality of cell strings CSTR as described above with reference to FIG. 2. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL. The second structure 1100S may correspond to, for example, the memory cell structure CELL as described above with reference to FIGS. 1 - 11.

In some embodiments of the present disclosure, the common source line CSL and the cell strings CSTR may be electrically connected to the decoder circuit 1110 via first connection lines 1115 extending from the first structure 1100F to the second structure 1100S.

In some embodiments of the present disclosure, the bit-lines BL may be electrically connected to the page buffer 1120 via second connection lines 1125.

The semiconductor memory device 1100 may communicate with the controller 1200 via an input/output pad 1101 electrically connected to the logic circuit 1130 (e.g., the control logic 67 in FIG. 1). The input/output pad 1101 may correspond to, for example, the conductive pad 390 as described above with reference to FIGS. 1 - 11. The input/output pad 1101 may be electrically connected to the logic circuit 1130 via an input/output connection line 1135 extending from the first structure 1100F to the second structure 1100S.

The controller 1200 may include a processor 1210, a NAND controller 1220, and a host interface 1230. In some embodiments of the present disclosure, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIGS. 20 - FIG. 21, an electronic system according to some embodiments of the present disclosure may include a main board 2001, a main controller 2002 mounted on the main board 2001, at least one semiconductor package 2003, and at least one DRAM 2004. The semiconductor package 2003 and he DRAM 2004 may be connected to the main controller 2002 via wiring patterns 2005 formed on the main board 2001.

The main board 2001 may include a connector 2006 including a plurality of pins coupled to an external host. The number and an arrangement of the plurality of pins in the connector 2006 may vary based on a communication interface between the electronic system 2000 and the external host. In some embodiments of the present disclosure, the electronic system 2000 may communicate with the external host using one of interfaces such as Universal Serial Bus (USB), Peripheral Component Interconnect Express (PCI-Express), Serial Advanced Technology Attachment (SATA), M-Phy for Universal Flash Storage (UFS), etc. In some embodiments of the present disclosure, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit substrate including package upper pads 2130. Each semiconductor chip 2200 may include an input/output pad 2210. The input/output pad 2210 may correspond to the input/output pad 1101 in FIG. 19.

In some embodiments of the present disclosure, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments of the present disclosure, in each of the first semiconductor package 2003a and the second semiconductor package 2003b, the semiconductor chips 2200 may be electrically connected to each other via a connection structure including a through electrode (e.g., a through silicon via (TSV)) instead of the connection structure 2400 using the bonding wire scheme.

In some embodiments of the present disclosure, the main controller 2002 and the semiconductor chips 2200 may be included in one package. In some embodiments of the present disclosure, the main controller 2002 and the semiconductor chips 2200 may be mounted on a separate interposer substrate different from the main board 2001, and the main controller 2002 and the semiconductor chips 2200 may be connected to each other via a wiring formed in the interposer substrate.

In some embodiments of the present disclosure, the package substrate 2100 may be embodied as a printed circuit substrate. The package substrate 2100 may include a package substrate body 2120, the package upper pads 2130 disposed on a upper surface of the package substrate body 2120, package lower pads 2125 disposed on a lower surface of the package substrate body 2120, or exposed through the lower surface thereof, and internal lines 2135 disposed in the package substrate body 2120 so as to electrically connect the package upper pads 2130 and the package lower pads 2125 to each other. The package upper pads 2130 may be electrically connected to the connection structures 2400. The package lower pads 2125 may be connected to the wiring patterns 2005 of the main board 2001 of the electronic system 2000 via conductive connectors 2800 as shown in FIG. 20.

In the electronic system 2000 according to some embodiments of the present disclosure, each of the semiconductor chips 2200 may include the semiconductor memory device as described above with reference to FIG. 1 to FIG. 11. For example, each of the semiconductor chips 2200 may include the peripheral circuit structure PERI and the memory cell structure CELL stacked on the peripheral circuit structure PERI. For example, the memory cell structure CELL may include the cell substrate 100, the stack structures (e.g., the first stack structure ST1 and the second stack structure ST2), the channel structure CH, the high dielectric-constant film HP, the cutting pattern WC, and the bit line BL, which are described above with reference to FIGS. 1 - 11.

According to some embodiments of the present disclosure, a method for manufacturing a semiconductor memory device may include: forming a pre-stack structure including a plurality of mold sacrificial films and a plurality of mold insulating films alternately stacked on top of each other in a first direction, forming a channel structure extending in the first direction and penetrating the pre-stack structure, forming a cutting pattern that cuts the pre-stack structure, removing the plurality of mold sacrificial films through an opening exposed through the cutting pattern, forming a first high dielectric-constant metal oxide film in contact with the channel structure through the opening, forming a second high dielectric-constant metal oxide film in contact with the first high dielectric-constant metal oxide film, and forming a stack structure by filling the opening with a plurality of gate electrodes, wherein the first high dielectric-constant metal oxide film includes a first metal oxide doped with an impurity element.

According to some embodiments of the present disclosure, the impurity element includes at least one from among germanium (Ge), indium (In), and gallium (Ga).

According to some embodiments of the present disclosure, a concentration of the impurity element in the first high dielectric-constant metal oxide film is in a range of 1 at% (atomic percent) inclusive to 50 at% inclusive.

According to some embodiments of the present disclosure, the second high dielectric-constant metal oxide film includes a second metal oxide different from the first metal oxide.

Although non-limiting example embodiments of the present disclosure have been described with reference to the accompanying drawings, the present disclosure is not limited to the example embodiments, and embodiments of the present disclosure may be implemented in various different forms. A person skilled in the art may appreciate that embodiments of the present disclosure may be practiced in other concrete forms without departing from the spirit and scope of the present disclosure. Therefore, it should be appreciated that the example embodiments as described above are illustrative, not restrictive, in all respects.

What is claimed is:

1. A semiconductor memory device comprising:
a substrate;
a stack structure on the substrate, the stack structure comprising gate electrodes and a mold insulating films, wherein the gate electrodes and the mold insulating films are alternately stacked on top of each other in a first direction intersecting an upper surface of the substrate;
a channel structure extending in the first direction through the stack structure, the channel structure comprising a semiconductor film and a data storage film between the semiconductor film and the gate electrodes; and
a high dielectric-constant film comprising:
a first high dielectric-constant metal oxide film in contact with the data storage film; and
a second high dielectric-constant metal oxide film between the first high dielectric-constant metal oxide film and at least one of the gate electrodes,
wherein the data storage film comprises a tunnel insulating film, a charge storage film, and a blocking insulating film sequentially disposed on the semiconductor film,
wherein the blocking insulating film is between the high dielectric-constant film and the charge storage film, and
wherein the first high dielectric-constant metal oxide film comprises a first metal oxide doped with an impurity element.

2. The semiconductor memory device of claim 1, wherein the impurity element comprises at least one from among germanium (Ge), indium (In), and gallium (Ga).

3. The semiconductor memory device of claim 1, wherein a concentration of the impurity element in the first high dielectric-constant metal oxide film is in a range of 1 at% (atomic percent) inclusive to 50 at% inclusive.

4. The semiconductor memory device of claim 1, wherein the second high dielectric-constant metal oxide film comprises a second metal oxide different from the first metal oxide.

5. The semiconductor memory device of claim 4, wherein the second metal oxide is free of the impurity element.

6. The semiconductor memory device of claim 1, wherein the first high dielectric-constant metal oxide film comprises:
a first portion between the channel structure and the at least one of the gate electrodes; and
a second portion disposed between the at least one of the gate electrodes and at least one of mold insulating films adjacent to the at least one of the gate electrodes.

7. The semiconductor memory device of claim 6, wherein a thickness of the first portion is greater than a thickness of the second portion.

8. The semiconductor memory device of claim 6, wherein the second high dielectric-constant metal oxide film comprises:
a third portion between the first portion and the at least one of the gate electrodes; and
a fourth portion between the second portion and the at least one of the gate electrodes.

9. The semiconductor memory device of claim 8, wherein a thickness of the first portion is greater than a thickness of the third portion.

10. The semiconductor memory device of claim 8, wherein a thickness of the third portion is greater than a thickness of the fourth portion.

11. The semiconductor memory device of claim 1, wherein the first high dielectric-constant metal oxide film is in contact with the blocking insulating film.

12. A semiconductor memory device comprising:
a substrate;
a stack structure on the substrate, the stack structure comprising gate electrodes and mold insulating films, wherein the gate electrodes and the mold insulating films are alternately stacked on top of each other in a first direction intersecting an upper surface of the substrate;
a channel structure extending in the first direction through the stack structure, the channel structure comprising a semiconductor film and a data storage film between the semiconductor film and the gate electrodes; and
a high dielectric-constant film between the channel structure and at least one of the gate electrodes and between at least one of the gate electrodes and at least one of the mold insulating films adjacent to the at least one of the gate electrodes,
wherein the high dielectric-constant film comprises:
a first high dielectric-constant metal oxide film in contact with the channel structure and the at least one of the mold insulating films, wherein the first high dielectric-constant metal oxide film comprises a first metal oxide doped with an impurity element; and
a second high dielectric-constant metal oxide film between the first high dielectric-constant metal oxide film and the at least one of the gate electrodes.

13. The semiconductor memory device of claim 12, wherein the data storage film comprises a tunnel insulating film, a charge storage film, and a blocking insulating film sequentially disposed on the semiconductor film,
wherein the first high dielectric-constant metal oxide film is in contact with the blocking insulating film.

14. The semiconductor memory device of claim 13, wherein the blocking insulating film is between the first high dielectric-constant metal oxide film and the charge storage film.

15. The semiconductor memory device of claim 12, wherein the impurity element comprises at least one from among germanium (Ge), indium (In), and gallium (Ga).

16. The semiconductor memory device of claim 12, wherein a concentration of the impurity element in the first high dielectric-constant metal oxide film is in a range of 1 at% inclusive to 50 at% inclusive.

17. The semiconductor memory device of claim 12, wherein the second high dielectric-constant metal oxide film comprises a second metal oxide different from the first metal oxide.

18. The semiconductor memory device of claim 17, wherein the second metal oxide is free of the impurity element.

19. An electronic system comprising:
a circuit board;
a semiconductor memory device on the circuit board; and
a controller on the circuit board and electrically connected to the semiconductor memory device,
wherein the semiconductor memory device comprises:
a substrate;
a stack structure on the substrate, the stack structure comprising gate electrodes and mold insulating films, wherein the gate electrodes and the molding insulating films are alternately stacked on top of each other in a first direction intersecting an upper surface of the substrate;
a channel structure extending in the first direction through the stack structure, the channel structure comprising a semiconductor film and a data storage film between the semiconductor film and the gate electrodes; and
a high dielectric-constant film comprising:
a first high dielectric-constant metal oxide film in contact with the data storage film; and
a second high dielectric-constant metal oxide film between the first high dielectric-constant metal oxide film and at least one of the gate electrodes,
wherein the data storage film comprises a tunnel insulating film, a charge storage film, and a blocking insulating film sequentially disposed on the semiconductor film,
wherein the blocking insulating film is between the high dielectric-constant film and the charge storage film, and
wherein the first high dielectric-constant metal oxide film comprises a first metal oxide doped with an impurity element.

20. The electronic system of claim 19, wherein the impurity element comprises at least one from among germanium (Ge), indium (In), and gallium (Ga).
